(19) United States
(12) Patent Application Publication
(10) Pub. No.: US 2026/0186032 A1
(43) Pub. Date: Jul. 2, 2026

(54) METHOD FOR ACCOUNTING FOR POWER LOSS

(71) Applicant: BH EVS Co., Ltd., Seoul (KR)

(72) Inventors: Kyung Hwan KIM, Seoul (KR); Yong Cheol PARK, Gwacheon-si Gyeonggi-do (KR); Seong Hun LEE, Seoul (KR)

(73) Assignee: BH EVS Co., Ltd., Seoul (KR)

(21) Appl. No.: 19/549,112

(22) Filed: Feb. 25, 2026

Related U.S. Application Data
(63) Continuation of application No. PCT/KR2024/012657, filed on Aug. 23, 2024.

(30) Foreign Application Priority Data
Aug. 25, 2023 (KR) 10-2023-0112267
Apr. 8, 2024 (KR) 10-2024-0047679

(51) Int. Cl. G01R 21/00; H02J 50/10; H02J 50/60; H02J 50/80; H02J 50/90

(52) U.S. Cl. CPC G01R 21/006; H02J 50/10; H02J 50/60; H02J 50/80; H02J 50/90

(57) ABSTRACT

Provided is a method for accounting for power loss. The method includes the steps of: acquiring information on a first distance between an upper surface of a coil of a wireless power transmitter and an upper surface of the wireless power transmitter, and a second distance between an upper surface of a coil of a reference transmitter and an upper surface of the reference transmitter; and estimating power loss due to friendly metal with reference to the acquired information.

### CROSS-REFERENCE TO RELATED APPLICATIONS

This application is a continuation of International Application No. PCT/KR2024/012657 filed on Aug. 23, 2024, which claims priority to Korean Patent Application No. 10-2023-0112267 filed on Aug. 25, 2023, and Korean Patent Application No. 10-2023-0047679 filed on Apr. 8, 2024, the entire contents of which are herein incorporated by reference.

### FIELD OF THE INVENTION

The present invention relates to a method for accounting for power loss.

### BACKGROUND

The Wireless Power Consortium (WPC) is an international standardization body in the field of wireless power transmission, responsible for establishing the Qi standard for inductive wireless charging. The Qi standard primarily defines the Baseline Power Profile (BPP) and Extended Power Profile (EPP), with the Magnetic Power Profile (MPP) recently introduced as a new addition.

For inductive wireless charging, a wireless power transmitter and a wireless power receiver are basically required, and it is essential that no foreign objects (FO) exist between the transmitter and receiver. If a foreign object is present between them, not only will charging performance degrade, but serious safety risks may also arise.

The Qi standard specifies various Foreign Object Detection (FOD) methods based on BPP and EPP, while the MPP Power Loss Accounting (MPLA) method is currently under discussion with respect to MPP-based FOD methods.

If we refer to the MPLA method currently under discussion as a conventional MPLA method, this requires estimating power loss caused by friendly metal (FM) in order to estimate (or account for) power loss due to foreign objects. However, since the conventional MPLA method estimates the power loss without considering a distance d_{z1} from a coil placed at the upper part of the wireless power transmitter to the upper surface of the wireless power transmitter, the linear model (i.e., linear fit curve) for power loss due to FM derived by the conventional MPLA method shows significant deviation from reality. This leads to substantial errors when estimating power loss due to FM in practical applications, directly resulting in degraded performance of the FOD methods.

### SUMMARY OF THE INVENTION

One object of the present invention is to solve all the above-described problems in the prior art.

Another object of the invention is to propose an improved MPLA method based on the analysis of physical causes that lead to errors when estimating power loss due to FM using a conventional MPLA method.

The representative configurations of the invention to achieve the above objects are described below.

According to one aspect of the invention, there is provided a method for accounting for power loss, the method comprising the steps of: acquiring information on a first distance between an upper surface of a coil of a wireless power transmitter and an upper surface of the wireless power transmitter, and a second distance between an upper surface of a coil of a reference transmitter and an upper surface of the reference transmitter; and estimating power loss due to friendly metal with reference to the acquired information.

According to another aspect of the invention, there is provided a wireless power transmitter, comprising: an acquisition unit configured to acquire information on a first distance between an upper surface of a coil of a wireless power transmitter and an upper surface of the wireless power transmitter, and a second distance between an upper surface of a coil of a reference transmitter and an upper surface of the reference transmitter; and an estimation management unit configured to estimate power loss due to friendly metal with reference to the acquired information.

According to yet another aspect of the invention, there is provided a method for accounting for power loss, the method comprising the steps of: acquiring information on a first distance between an upper surface of a coil of a wireless power transmitter and an upper surface of the wireless power transmitter, and a second distance between an upper surface of a coil of a reference transmitter and an upper surface of the reference transmitter; and causing power loss due to friendly metal to be estimated with reference to the acquired information.

According to still another aspect of the invention, there is provided a wireless power receiver, comprising: an acquisition unit configured to acquire information on a first distance between an upper surface of a coil of a wireless power transmitter and an upper surface of the wireless power transmitter, and a second distance between an upper surface of a coil of a reference transmitter and an upper surface of the reference transmitter; and an estimation management unit configured to cause power loss due to friendly metal to be estimated with reference to the acquired information.

In addition, there are further provided other methods, wireless power transmitters, and wireless power receivers to implement the invention.

According to the invention, the improved MPLA method may demonstrate superior RMSE (Root Mean Squared Error) performance compared to the conventional MPLA method, and may enhance FOD performance when implemented in MPP-based wireless power transmitters and receivers.

### BRIEF DESCRIPTION OF THE DRAWINGS

FIG. 1 shows a loss-split model for a wireless power transmitters and a wireless power receiver.

FIGS. 2A, 2B and 2C show linear models derived by a conventional MPLA method.

FIGS. 3A and 3B show a result of comparing a linear model for power loss due to FM derived by the conventional MPLA method and an ideal linear model for power loss due to FM.

FIGS. 4A, 4B, 5A, 5B, 6A, 6B, 7A and 7B schematically show components of the wireless power transmitter and wireless power receiver.

FIG. 8 shows linear models derived by the conventional MPLA method under GG, TG, and GR conditions for a general transmitter with d_{z1} of 2.0 mm.

FIG. 9 shows a linear model for power loss due to FM derived by the conventional MPLA method under a TR condition for a general transmitter with d_{z1} of 2.0 mm.

FIG. 10 shows linear models derived by an improved MPLA method under GG, TG, and GR conditions for a general transmitter with d_{z1} of 2.0 mm.

FIG. 11 shows a linear model for power loss due to FM derived by the improved MPLA method under a TR condition for a general transmitter with d_{z1} of 2.0 mm.

FIG. 12 shows linear models derived by the conventional MPLA method under GG, TG, and GR conditions for a general transmitter with d_{z1} of 4.0 mm.

FIG. 13 shows a linear model for power loss due to FM derived by the conventional MPLA method under a TR condition for a general transmitter with d_{z1} of 4.0 mm.

FIG. 14 shows linear models derived by the improved MPLA method under GG, TG, and GR conditions for a general transmitter with d_{z1} of 4.0 mm.

FIG. 15 shows a linear model for power loss due to FM derived by the improved MPLA method under a TR condition for a general transmitter with d_{z1} of 4.0 mm.

### DETAILED DESCRIPTION

In the following detailed description of the present invention, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different from each other, are not necessarily mutually exclusive. For example, specific shapes, structures and characteristics described herein may be implemented as modified from one embodiment to another without departing from the spirit and scope of the invention. Furthermore, it shall be understood that the positions or arrangements of individual elements within each embodiment may also be modified without departing from the spirit and scope of the invention. Therefore, the following detailed description is not to be taken in a limiting sense, and the scope of the invention is to be taken as encompassing the scope of the appended claims and all equivalents thereof. In the drawings, like reference numerals refer to the same or similar elements throughout the several views.

The term “estimating” herein may be used interchangeably with terms such as “accounting for,” “calculating,” or “measuring” in some cases, and vice versa.

Hereinafter, various preferred embodiments of the invention will be described in detail with reference to the accompanying drawings to enable those skilled in the art to easily implement the invention.

### Background of Proposal of the Improved MPLA Method

MPP is a power profile newly introduced in the Qi2 standard, with discussions starting based on Apple's MagSafe. Compared to the existing BPP and EPP, MPP is characterized by the inclusion of an additional element, i.e., a magnet that aligns and fixes a wireless power transmitter (hereinafter, “transmitter” or “PTx”) and a wireless power receiver (hereinafter, “receiver” or “PRx”).

As discussed in the background section, establishing an FOD (Foreign Object Detection) method is very important for MPP as well as for BPP and EPP. The conventional MPLA method, which is discussed as an FOD method for MPP, is planned to be implemented as follows.

In the conventional MPLA method, power loss due to foreign objects P_{FO} is estimated as a difference between transmitted power P_{PT} and received power P_{PR}. In other words, a relationship equation P_{FO}=P_{PT}−P_{PR} holds. Here, P_{PR} is estimated by the transmitter through a relationship equation P_{PT}=V_{IN}I_{IN}−(P_{circuit loss,Tx}+P_{coil loss,Tx}+P_{FM}), and P_{PR} is estimated by the receiver through a relationship equation P_{PR}=V_{RECT}I_{RECT}+P_{circuit loss,Rx}+P_{coil loss,Rx}. That is, in order to estimate P_{FO}, the transmitter should estimate an input voltage V_{IN}, input current I_{IN}, transmitter-side circuit power loss P_{circuit loss,Tx}, transmitter-side coil power loss P_{coil loss,Tx}, and power loss due to friendly metal P_{FM}. Further, the receiver should estimate a rectified voltage V_{RECT}, rectified current I_{RECT}, receiver-side circuit power loss P circuit loss,Rx, and receiver-side coil power loss P_{coil loss,Rx}. Under a TR condition (details of which will be described later), P_{coil loss,Tx}, P_{coil loss,Rx}, and P_{FM} are estimated through relationship equations P_{coil loss,Tx}=g_{coil,Tx}b_{coil}R_{coil air,Tx}I_{Tx}², P_{coil loss,Rx}=I_{coil,Rx}m_{coil}R_{coil air,Rx}I_{RECT}², and P_{FM}≈g_{FM}α_{FM}I_{Tx}²+g_{FM,DC}α_{FM,DC}, respectively. Here, b_{coil}, m_{coil}, α_{FM}, and α_{FM,DC} may be referred to as MPLA coefficients or PLA coefficients, and g_{coil,Tx}, g_{coil,Rx}, g_{FM}, and g_{FM,DC} may be referred to as scaling factors or ecosystem scaling factors.

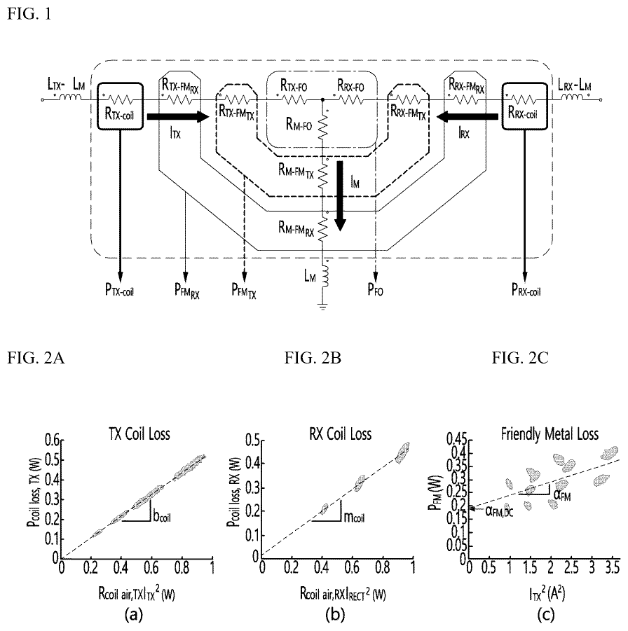

A loss-split model for the transmitter and receiver as shown in FIG. 1 is used to derive linear models (i.e., linear fit curves) as shown in FIGS. 2A, 2B and 2C, and then the MPLA coefficients are calculated from the slopes and intercepts of the curves.

The scaling factors are commonly defined as

$$\text{?} = \text{?} / \text{?} \approx \text{?} / \text{?} ,$$

$$\text{?} = \text{?} / \text{?} \approx \text{?} / \text{?} ,$$

$${g}_{FM} = {α}_{FM}^{TG} / {α}_{FM}^{GG} \approx {α}_{FM}^{TR} / {α}_{FM}^{GR} ,$$

$$and$$

$${g}_{FM , DC} = {α}_{FM , DC}^{TG} / {α}_{FM , DC}^{GG} \approx {α}_{FM , DC}^{TR} / {α}_{FM , DC}^{GR} ,$$

$$\text{?} \text{indicates text missing or illegible when filed}$$

respectively. Here, superscripts GG, TG, GR, and TR are used to distinguish various transmitter/receiver pairs. Specifically, GG refers to the case where the transmitter is a reference transmitter defined by the Qi standard (Ref. PTx (TPT)) and the receiver is also a reference receiver defined by the Qi standard (Ref. PRx (TPR)). TG refers to the case where the transmitter is a general (or unknown) transmitter (General PTx) and the receiver is a reference receiver defined by the Qi standard (Ref. PRx (TPR)). GR refers to the case where the transmitter is a reference transmitter defined by the Qi standard (Ref. PTx (TPT)) and the receiver is a general (or unknown) receiver (General PRx). TR refers to the case where the transmitter is a general (or unknown) transmitter (General PTx) and the receiver is also a general (or unknown) receiver (General PRx). The conventional MPLA method ultimately aims to derive results under a TR condition, and the improved MPLA method to be described later follows the same goal.

d_{z1} refers to a distance from a coil placed at a transmitter to an upper surface of the transmitter. Specifically, d_{z1} refers to a distance from an upper surface of a coil placed at a transmitter to an upper surface of an interface of the transmitter.

The conventional MPLA method estimates power loss of a general transmitter without considering d_{z1} of the general transmitter, but limiting d_{z1} of the reference transmitter to 1.2 mm. However, the Qi standard does not mandate that d_{z1} of the general transmitter must be 1.2 mm, and d_{z1} of the general transmitter may vary depending on its use. Actually, while it is common to design d_{z1} as 1.2 mm for household wireless power transmitters, vehicle wireless power transmitters may need to increase d_{z1} to 1.2 mm or more due to mechanical/structural issues such as housing thickness, anti-slip pads, EMI (Electro Magnetic Interference) shielding pattern PCBs (Printed Circuit Boards), and air flow paths for heat dissipation. Therefore, it is necessary to estimate the power loss of the general transmitter after adjusting d_{z1} of the reference transmitter (which may be referred to as a second distance) to match d_{z1} of the general transmitter (which may be referred to as a first distance).

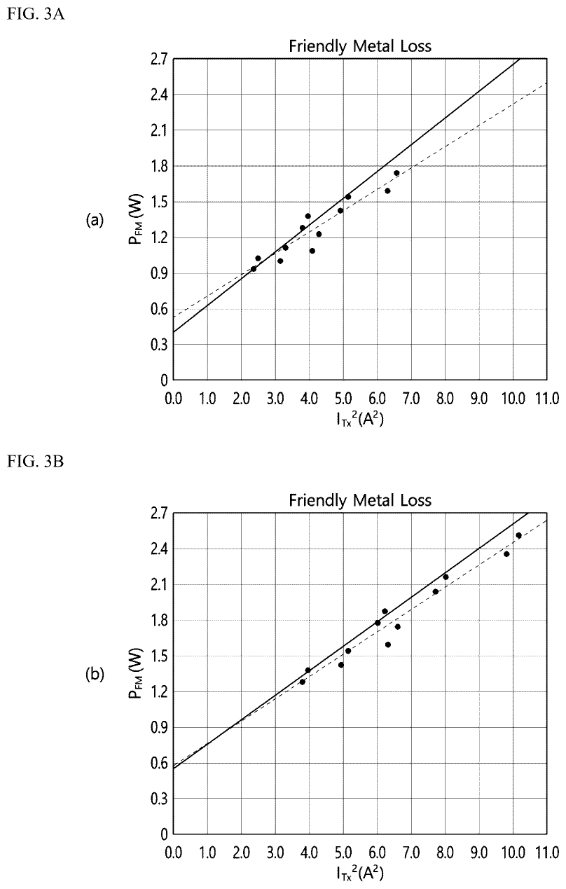

FIG. 3A shows both a linear model for P_{FM} derived by the conventional MPLA method and an ideal linear model for P_{FM} under a TR condition for a general transmitter with d_{z1} of 2.0 mm, and FIG. 3B shows both a linear model for P_{FM} derived by the conventional MPLA method and an ideal linear model for P_{FM} under a TR condition for a general transmitter with d_{z1} of 4.0 mm. The model shown with a dotted line is the ideal linear model for P_{FM}, and the model shown with a solid line is the linear model for P_{FM} derived by the conventional MPLA method. Referring to FIGS. 3A and 3B, there is a significant difference between the linear model for P_{FM} derived by the conventional MPLA method and the ideal linear model for P_{FM} for the general transmitter. This causes significant errors when estimating P_{FM} in practical applications, which directly leads to degradation in performance of the FOD method.

The improved MPLA method proposed in the invention may estimate P_{FM} with reference to d_{z1} of the reference transmitter and d_{z1} of the general transmitter. Specifically, P_{FM} may be estimated by adjusting d_{z1} of the reference transmitter to be equal to d_{z1} of the general transmitter.

First, regarding the influence of d_{z1} on P_{FM}, leakage magnetic flux increases and interacts with a larger area of friendly metal as d_{z1} increases. Due to this phenomenon, the values of the scaling factors may change as d_{z1} varies even under the same wireless power transmitter conditions, and the changes in the scaling factor values inevitably cause changes in P_{FM}.

Based on this insight, in the improved MPLA method proposed in the invention, P_{FM} is estimated after adjusting d_{z1} of the reference transmitter to match d_{z1} of the general transmitter. Specifically, for the measurement-based MPLA method, the improved MPLA method may be performed after a gap (e.g., air or transparent acrylic) equal to the difference between d_{z1} of the general transmitter and d_{z1} of the reference transmitter is placed on the interface of the reference transmitter. For the simulation-based MPLA method and the loss-based model, the improved MPLA method may be performed by placing a receiver that reflects the difference between d_{z1} of the general transmitter and d_{z1} of the reference transmitter in a finite element analysis (FEA) simulation space.

### Improved MPLA Method

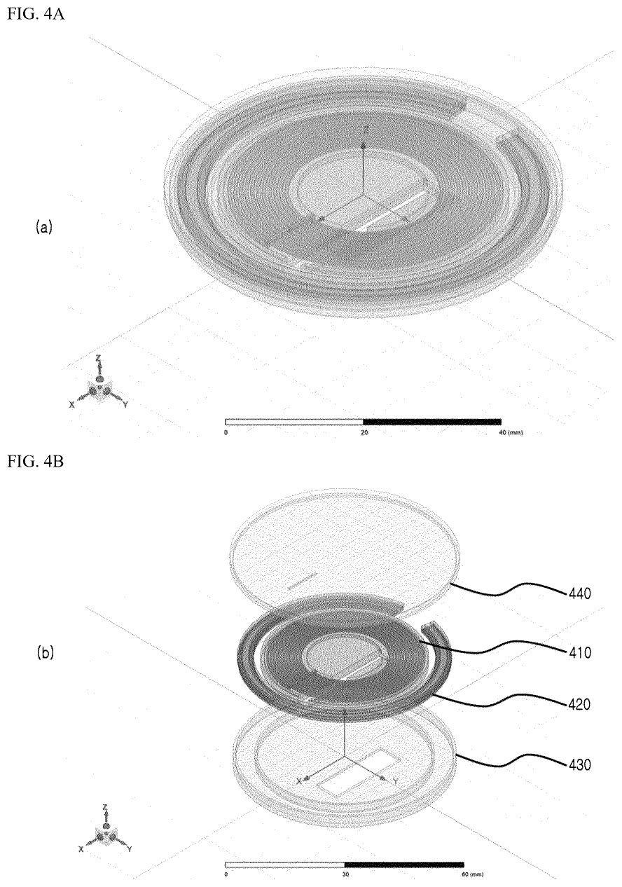

According to one embodiment of the invention, the transmitter and receiver may include basic configurations for wireless charging by magnetic induction, such as a coil module, and a magnet may be additionally included in the transmitter for MPP applications. Further, the receiver may include friendly metal. The configurations of the transmitter and receiver are shown in FIGS. 4A to 7B.

Specifically, FIGS. 4A and 4B show a perspective view and an exploded perspective view of a reference transmitter (Ref. PTx (TPT)) defined by the Qi standard, respectively. As shown in FIGS. 4A and 4B, the transmitter may include a coil 410, a magnet 420, a lower enclosure 430, and an upper enclosure 440. Here, the coil 410 may be configured to operate on the basis of MPP, and the magnet 420 may be formed to at least partially surround the coil 410.

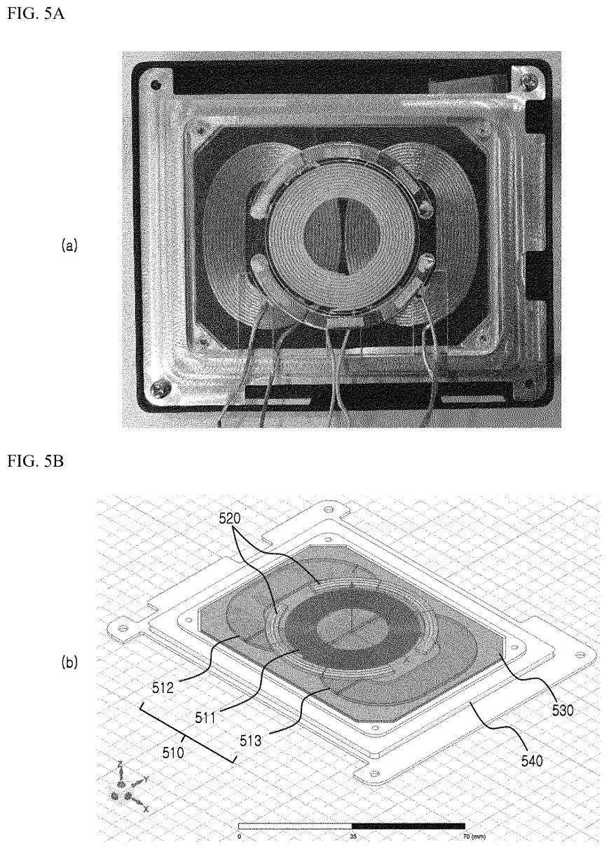

Further, FIGS. 5A and 5B show a plan view and a perspective view of a general (or unknown) transmitter (General PTx), respectively. Unlike the perspective view, the plan view shows a prototype rather than a modeled drawing. As shown in FIGS. 5A and 5B, the transmitter may include a coil 510, a magnet 520, ferrite 530, and a bracket 540. Specifically, the coil 510 may consist of one coil 511 disposed at the upper part and two coils 512, 513 disposed at the lower part, and the upper coil 511 may be configured to operate on the basis of MPP. Further, the magnet 520 may be formed to at least partially surround the upper coil 511. For example, the magnet 520 may basically have a circular shape, with arcs having a central angle of 150 degrees alternatingly arranged. The bracket 540 may be made of aluminum.

Meanwhile, in the transmitter, a distance d_{z1} from the upper coil 511 to the upper surface of the transmitter may be 1.2 mm, and a distance from the magnet (520) to the upper surface of the transmitter may be 0.9 mm. However, d_{z1} is not limited to 1.2 mm and may vary depending on use of the transmitter. For example, d_{z1} for a household transmitter may be 1.2 mm, whereas d_{z1} for a vehicle transmitter may be 2.0 mm or more due to mechanical/structural issues such as housing thickness, anti-slip pads, EMI shielding pattern PCBs, and air flow paths for heat dissipation.

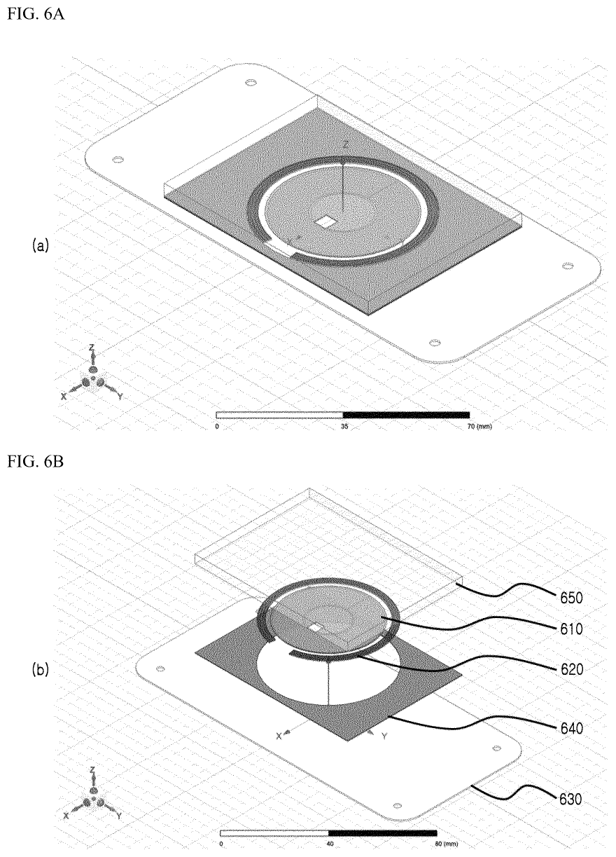

Further, FIGS. 6A and 6B show a perspective view and an exploded perspective view of a reference receiver (Ref. PRx (TPR)) defined by the Qi standard, respectively. As shown in FIGS. 6A and 6B, the receiver may include a coil 610, a magnet 620, a lower enclosure 630, a support plate 640, and friendly metal 650. Here, the coil 610 may operate on the basis of MPP, and the magnet 620 may be formed to at least partially surround the coil 610. The thickness of the friendly metal 650 may be 4.3 mm.

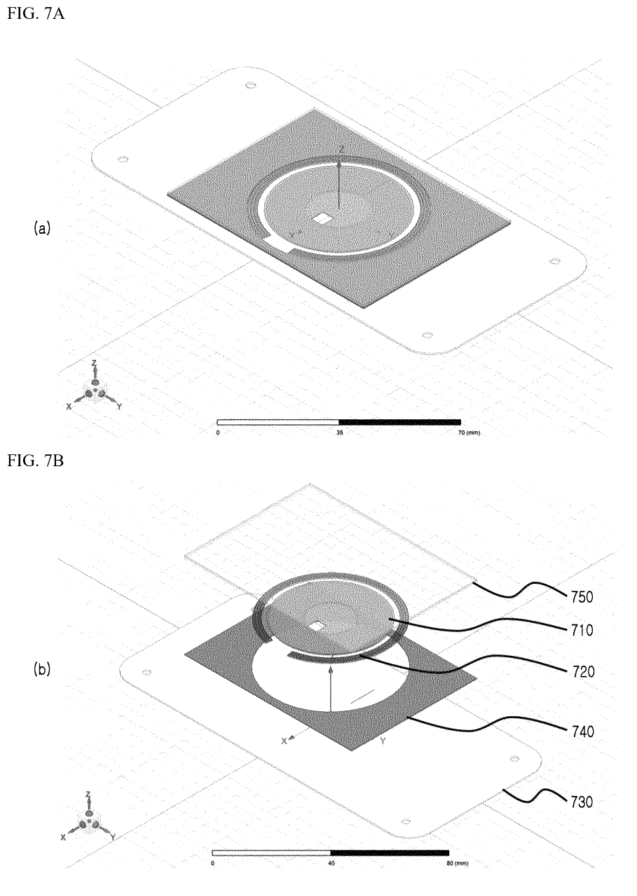

Further, FIGS. 7A and 7B show a perspective view and an exploded perspective view of a general (or unknown) receiver (General PRx), respectively. As shown in FIGS. 7A and 7B, the receiver may include a coil 710, a magnet 720, a lower enclosure 730, a support plate 740, and friendly metal 750. Here, the coil 710 may operate on the basis of MPP, and the magnet 720 may be formed to at least partially surround the coil 710. The thickness of the friendly metal 750 may be 0.7 mm. As the thickness of the friendly metal is smaller, open-air R is larger and open-air Q is smaller. The receiver as shown in FIGS. 7A and 7B may have thinner friendly metal compared to the receiver as shown in FIGS. 6A and 6B. Except for the thickness and d_{z1} of the friendly metal, the components of the receiver as shown in FIGS. 7A and 7B may be identical to those of the receiver as shown in FIGS. 6A and 6B.

Meanwhile, according to one embodiment of the invention, the transmitter and receiver may each include a configuration (not shown) for computational processing. This configuration may be referred to as a control circuit, and may consist of components such as a processor and memory. Further, this configuration may be formed as functional modules. For example, the configuration for computational processing may be formed as modules referred to as an acquisition unit, an estimation management unit, and the like in each of the transmitter and receiver. These functional modules may be understood as included in the aforementioned control circuit. The improved MPLA method will be described with the functional modules as the main entities.

According to one embodiment of the invention, when a general transmitter performs the improved MPLA method, the acquisition unit may acquire information on a first distance between an upper surface of a coil of the general transmitter and an upper surface of the general transmitter (i.e., d_{z1} of the general transmitter), and a second distance between an upper surface of a coil of a reference transmitter and an upper surface of the reference transmitter (i.e., d_{z1} of the reference transmitter), and the estimation management unit may estimate power loss due to friendly metal with reference to the acquired information.

According to one embodiment of the invention, the improved MPLA method described as being performed by the functional modules may also be described as being performed by the transmitter or receiver itself as the main entity, or by the control circuit included in the transmitter or receiver as the main entity.

Hereinafter, an embodiment where the improved MPLA method is implemented under the condition that the general receiver cooperates (hereinafter, “first embodiment”) and an embodiment where the improved MPLA method is implemented under the condition that the general receiver does not cooperate (hereinafter, “second embodiment”) will be described. Meanwhile, although the embodiments described below are described with the transmitter or receiver as the main entity, it should be noted that the embodiments may also be described with the aforementioned control circuit or functional modules as the main entities.

### First Embodiment: Improved MPLA Method Under the Condition that the General Receiver Cooperates

In this embodiment, under the condition where d_{z1} of the general transmitter is 2.0 mm or 4.0 mm, simulations of the conventional MPLA method and the improved MPLA method are performed to compare and evaluate their performance, and then it is described how to implement the improved MPLA method in the transmitter and receiver.

Meanwhile, the simulations are also performed under the condition where load power, which is defined as the product of V_{RECT} and I_{RECT}, is 10 W, 12.5 W, and 15 W, in addition to the above condition. Further, the simulations are performed under the condition where the transmitter is located at (0, 0, 0) and the receiver is located at (0, 0, 0), (0, 0, 2), (2, 0, 0), and (2, 0, 2) in a three-dimensional orthogonal coordinate system. Here, when the y-coordinate is omitted from the receiver's coordinates, the simulations may also be represented as performed at (0, 0), (0, 2), (2, 0), and (2, 2).

According to one embodiment of the invention, the conventional MPLA method derives a linear model for P_{FM} without considering d_{z1} of the general transmitter, but limiting d_{z1} of the reference transmitter to 1.2 mm, whereas the improved MPLA method may derive a linear model for P_{FM} after adjusting d_{z1} of the reference transmitter to match d_{z1} of the general transmitter.

First, simulation results under the condition that d_{z1} of the general transmitter is 2.0 mm will be described.

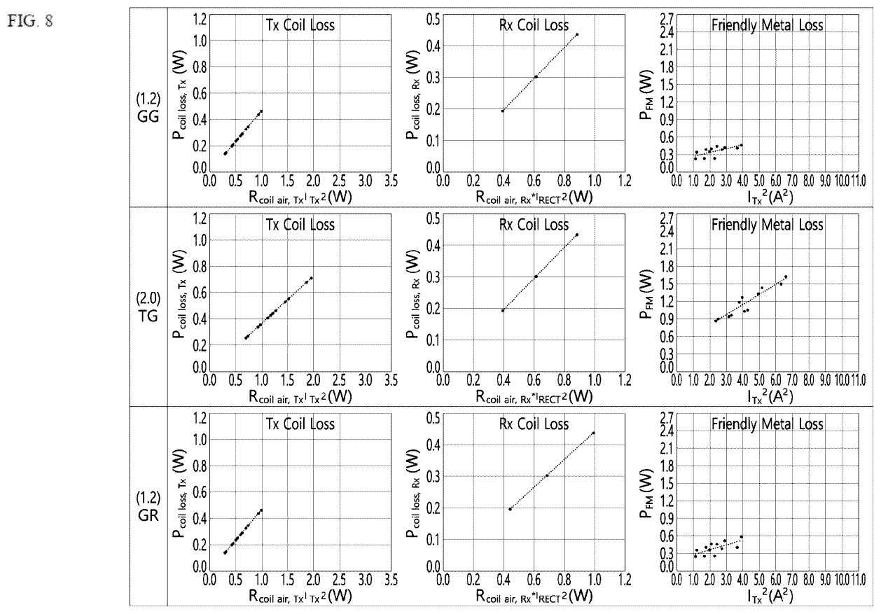

As shown in FIG. 8, the conventional MPLA method derives linear models for P_{FM} by limiting d_{z1} of the reference transmitter to 1.2 mm under GG, TG, and GR conditions for the general transmitter with d_{z1} of 2.0 mm. The MPLA coefficients under each condition are shown in Table 1.

TABLE 1

| | b_{coil} | m_{coil} | α_{FM} | α_{FM, DC} |
|---|---|---|---|---|
| GG | 0.4647 | 0.4939 | 0.0670 | 0.2016 |
| TG | 0.3661 | 0.4939 | 0.1791 | 0.4273 |
| GR | 0.4649 | 0.4385 | 0.0837 | 0.1906 |

Further, the scaling factors under each condition are shown in Table 2.

TABLE 2

| g_{coil, Tx} | g_{coil, Rx} | g_{FM} | g_{FM, DC} |
|---|---|---|---|
| 1.000 | 1.000 | 2.6731 | 2.120 |

In the conventional MPLA method under the TR condition, the estimated value of P_{coil loss,Tx} is calculated as

$${\hat{P}}_{coil loss , Tx} = {b}_{coil}^{TR} {R}_{coil air , Tx} {I}_{Tx}^{2} \approx {g}_{coil , Tx} {b}_{coil}^{TG} {R}_{coil air , Tx} {I}_{Tx}^{2} = {b}_{coil}^{TG} {R}_{coil air , Tx} {I}_{Tx}^{2} = 0.3661 {R}_{coil air , Tx} {I}_{Tx}^{2} ,$$

and the estimated value of P_{coil loss,Rx} is calculated as

$${\hat{P}}_{coil loss , Rx} = {m}_{coil}^{TR} {R}_{coil air , Rx} {I}_{RECT}^{2} \approx {g}_{coil , Rx} {m}_{coil}^{GR} {R}_{coil air , Rx} {I}_{RECT}^{2} = {m}_{coil}^{GR} {R}_{coil air , Rx} {I}_{RECT}^{2} = 0.4385 {R}_{coil air , Rx} {I}_{RECT}^{2} .$$

Additionally, in the conventional MPLA method under the TR condition, the estimated value of P_{FM} is calculated as

$${\hat{P}}_{FM} = {α}_{FM}^{TR} {I}_{Tx}^{2} + {α}_{FM , DC}^{TR} \approx {g}_{FM} {α}_{FM}^{GR} {I}_{Tx}^{2} + {g}_{FM , DC} {α}_{FM , DC}^{GR} = 2.6731 \times 0.0837 {I}_{Tx}^{2} + 2.12 \times 0.1906 = 0.2237 {I}_{Tx}^{2} + 0.404 .$$

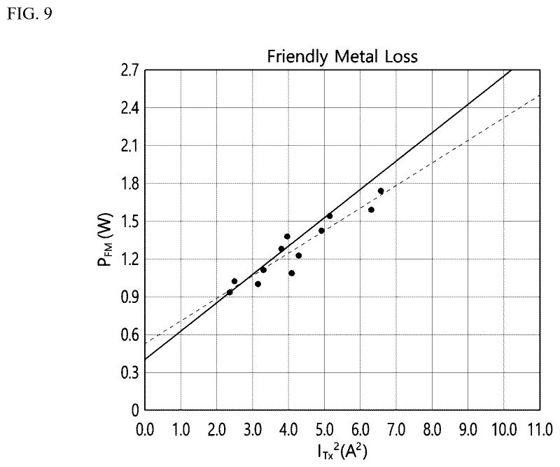

FIG. 9 shows a linear model for P_{FM} derived by the conventional MPLA method under the TR condition for the general transmitter with d_{z1} of 2.0 mm. The model shown with a dotted line is an ideal linear model for P_{FM}, in which case the estimated value of P_{FM} is

$${\hat{P}}_{FM} = 0.1802 {I}_{Tx}^{2} + 0.5215 .$$

Further, the model shown with a solid line is a model derived by the conventional MPLA method. In this case, the estimated value of P_{FM} is

$${\hat{P}}_{FM} = 0.2237 {I}_{Tx}^{2} + 0.404 .$$

According to one embodiment of the invention, RMSEs of the two models shown in FIG. 9 are shown in Table 3. The unit is mW.

TABLE 3

| | Ideal | Model according to the |
|---|---|---|
| | model | conventional MPLA method |
| RMSE | 83.8 | 120 |

According to one embodiment of the invention, the conventional MPLA method shows RMSE performance degradation of about 44.1% compared to the ideal model.

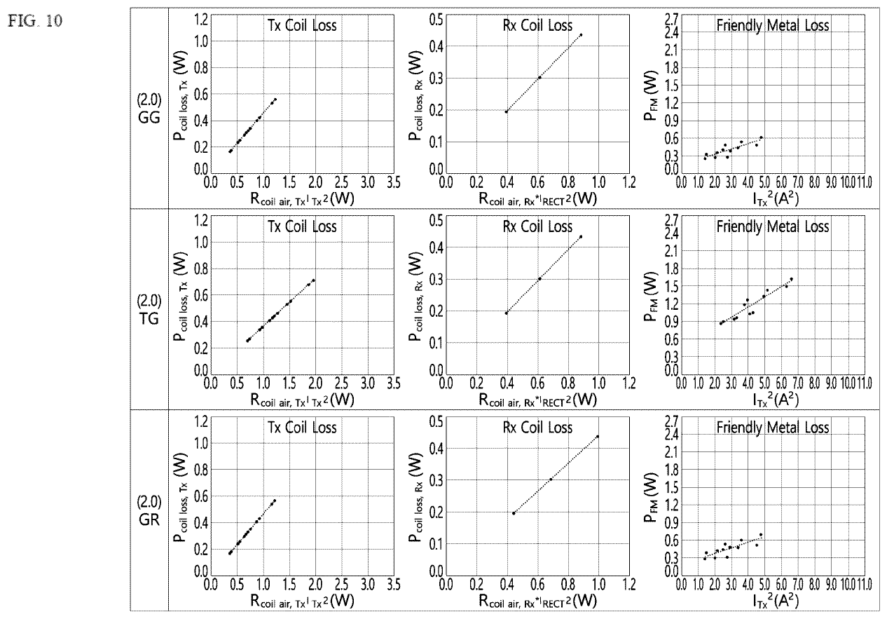

As shown in FIG. 10, the improved MPLA method according to one embodiment of the invention derives linear models for P_{FM} after adjusting d_{z1} of the reference transmitter to 2.0 mm under GG, TG, and GR conditions for the general transmitter with d_{z1} of 2.0 mm. The MPLA coefficients under each condition are shown in Table 4.

TABLE 4

| | b_{coil} | m_{coil} | α_{FM} | α_{FM, DC} |
|---|---|---|---|---|
| GG | 0.4648 | 0.4939 | 0.0896 | 0.1542 |
| TG | 0.3661 | 0.4939 | 0.1791 | 0.4273 |
| GR | 0.4650 | 0.4385 | 0.0955 | 0.1829 |

Further, the scaling factors after adjusting d_{z1} of the reference transmitter to 2.0 mm are shown in Table 5.

TABLE 5

| g_{coil, Tx} | g_{coil, Rx} | g_{FM} | g_{FM, DC} |
|---|---|---|---|
| 1.000 | 1.000 | 1.9989 | 2.7711 |

According to one embodiment of the invention, the improved MPLA method may estimate P_{FM} after adjusting d_{z1} of the reference transmitter to match d_{z1} of the general transmitter under the TR condition for the general transmitter with d_{z1} of 2.0 mm.

Specifically, when d_{z1} of the reference transmitter is adjusted to match d_{z1} of the general transmitter (i.e., 2.0 mm), the estimated value of P_{coil loss,Tx} is calculated as

$${\hat{P}}_{coil loss , Tx} = {b}_{coil}^{TR} {R}_{coil air , Tx} {I}_{Tx}^{2} \approx {g}_{coil , Tx} {b}_{coil}^{TG} {R}_{coil air , Tx} {I}_{Tx}^{2} = {b}_{coil}^{TG} {R}_{coil air , Tx} {I}_{Tx}^{2} = 0.3661 {R}_{coil air , Tx} {I}_{Tx}^{2} ,$$

and the estimated value of P_{coil loss,Rx} is calculated as

$${\hat{P}}_{coil loss , Rx} = {m}_{coil}^{TR} {R}_{coil air , Rx} {I}_{RECT}^{2} \approx {g}_{coil , Rx} {m}_{coil}^{GR} {R}_{coil air , Rx} {I}_{RECT}^{2} = {m}_{coil}^{GR} {R}_{coil air , Rx} {I}_{RECT}^{2} = 0.4385 {R}_{coil air , Rx} {I}_{RECT}^{2} .$$

The estimated value of P_{FM} is calculated as

$${\hat{P}}_{FM} = {α}_{FM}^{TR} {I}_{Tx}^{2} + {α}_{FM , DC}^{TR} \approx {g}_{FM} {α}_{FM}^{GR} {I}_{Tx}^{2} + {g}_{FM , DC} {α}_{FM , DC}^{GR} = 1.9989 \times {0.0955}_{Tx}^{2} + 2.7711 \times 0.1829 = 0.1909 {I}_{Tx}^{2} + 0.5068 .$$

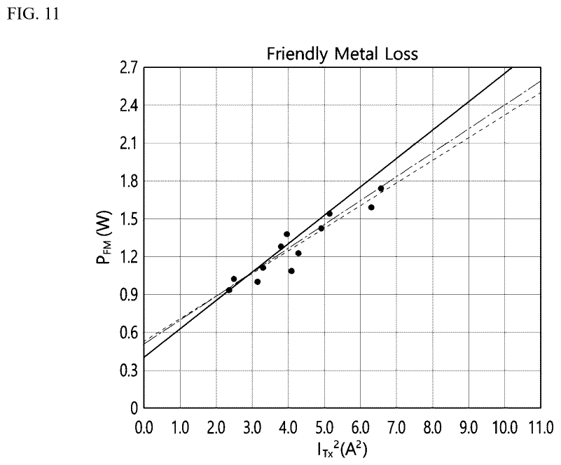

FIG. 11 shows a linear model for PPM derived by the improved MPLA method under the TR condition for the general transmitter with d_{z1} of 2.0 mm. The model shown with a dash-dotted line in FIG. 11 is a model derived by the improved MPLA method, and the estimated value of P_{FM} is

$${\hat{P}}_{FM} = 0.1909 {I}_{Tx}^{2} + 0.5068 .$$

The model shown with a solid line is a model derived by the conventional MPLA method, and the estimated value of P_{FM} is

$${\hat{P}}_{FM} = 0.2237 {I}_{Tx}^{2} + 0.404 .$$

The model shown with a dotted line is an ideal model, and the estimated value of P_{FM} is

$${\hat{P}}_{FM} = 0.1802 {I}_{Tx}^{2} + 0.5215 .$$

According to one embodiment of the invention, RMSEs of the three models shown in FIG. 11 are shown in Table 6. The unit is mW.

TABLE 6

| | | Model according to | Model according |
|---|---|---|---|
| | Ideal | the conventional | to the improved |
| | model | MPLA method | MPLA method |
| RMSE | 83.8 | 120 | 89.8 |

According to one embodiment of the invention, the model according to the improved MPLA method demonstrates RMSE performance advantage of about 25.2% compared to the model according to the conventional MPLA method.

Next, simulation results under the condition that d_{z1} of the general transmitter is 4.0 mm will be described.

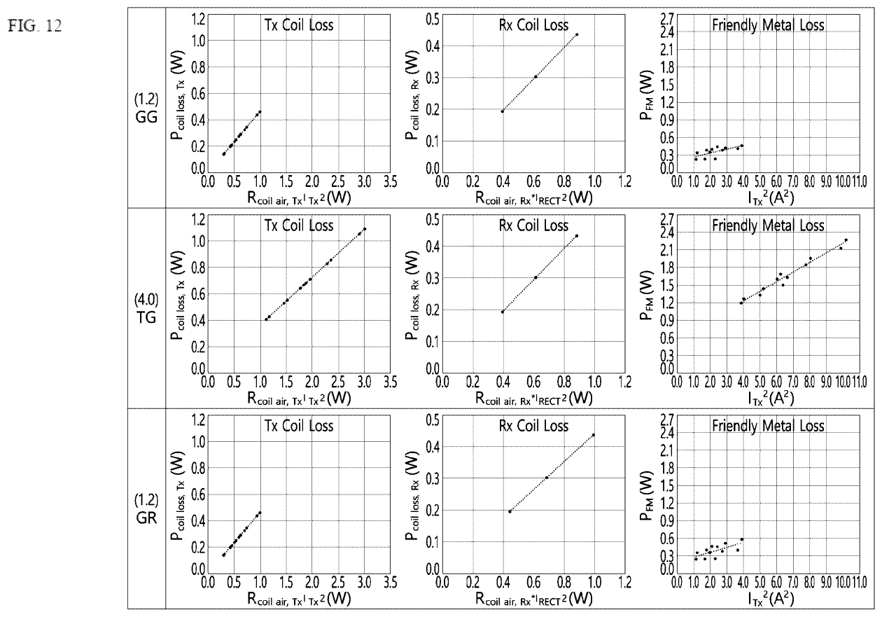

As shown in FIG. 12, the conventional MPLA method derives linear models for P_{FM} by limiting d_{z1} of the reference transmitter to 1.2 mm under GG, TG, and GR conditions for the general transmitter with d_{z1} of 4.0 mm. The MPLA coefficients under each condition are shown in Table 7.

TABLE 7

| | b_{coil} | m_{coil} | α_{FM} | α_{FM, DC} |
|---|---|---|---|---|
| GG | 0.4647 | 0.4939 | 0.0670 | 0.2016 |
| TG | 0.3661 | 0.4939 | 0.1651 | 0.5803 |
| GR | 0.4649 | 0.4385 | 0.0837 | 0.1906 |

Further, the scaling factors under each condition are shown in Table 8.

TABLE 8

| g_{coil, Tx} | g_{coil, Rx} | g_{FM} | g_{FM, DC} |
|---|---|---|---|
| 1.000 | 1.000 | 2.4642 | 2.8785 |

In the conventional MPLA method under the TR condition, the estimated value of P_{coil loss,Tx} is calculated as

$${\hat{P}}_{coil loss , Tx} = {b}_{coil}^{TR} {R}_{coil air , Tx} {I}_{Tx}^{2} \approx {g}_{coil , Tx} {b}_{coil}^{TG} {R}_{coil air , Tx} {I}_{Tx}^{2} = {b}_{coil}^{TG} {R}_{coil air , Tx} {I}_{Tx}^{2} = 0.3661 {R}_{coil air , Tx} {I}_{Tx}^{2} ,$$

and the estimated value of P_{coil loss,Rx} is calculated as

$${\hat{P}}_{coil loss , Rx} = {m}_{coil}^{TR} {R}_{coil air , Rx} {I}_{RECT}^{2} \approx {g}_{coil , Rx} {m}_{coil}^{GR} {R}_{coil air , Rx} {I}_{RECT}^{2} = {m}_{coil}^{GR} {R}_{coil air , Rx} {I}_{RECT}^{2} = 0.4385 {R}_{coil air , Rx} {I}_{RECT}^{2} .$$

Additionally, in the conventional MPLA method under the TR condition, the estimated value of P_{FM} is calculated as

$${\hat{P}}_{FM} = {α}_{FM}^{TR} {I}_{Tx}^{2} + {α}_{FM , DC}^{TR} \approx {g}_{FM} {α}_{FM}^{GR} {I}_{Tx}^{2} + {g}_{FM , DC} {α}_{FM , DC}^{GR} = 2.4642 \times {0.0837}_{Tx}^{2} + 2.8785 \times 0.1906 = 0.2063 {I}_{Tx}^{2} + 0.5486 .$$

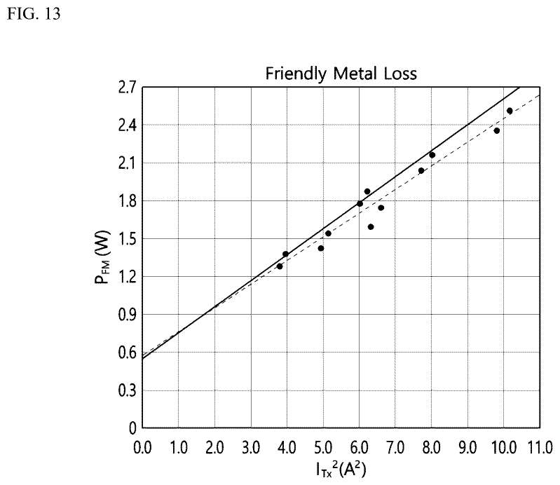

FIG. 13 shows a linear model for P_{FM} derived by the conventional MPLA method under the TR condition for the general transmitter with d_{z1} of 4.0 mm. The model shown with a dotted line is an ideal linear model for P_{FM}, in which case the estimated value of P_{FM} is

$${\hat{P}}_{FM} = 0.187 {I}_{Tx}^{2} + 0.5802 .$$

Further, the model shown with a solid line is a model derived by the conventional MPLA method. In this case, the estimated value of P_{FM} is

$${\hat{P}}_{FM} = 0.2063 {I}_{Tx}^{2} + 0.5486 .$$

According to one embodiment of the invention, RMSEs of the two models shown in FIG. 13 are shown in Table 9. The unit is mW.

TABLE 9

| | Ideal | Model according to the |
|---|---|---|
| | model | conventional MPLA method |
| RMSE | 80.9 | 130.4 |

According to one embodiment of the invention, the conventional MPLA method shows RMSE performance degradation of about 61.2% compared to the ideal model.

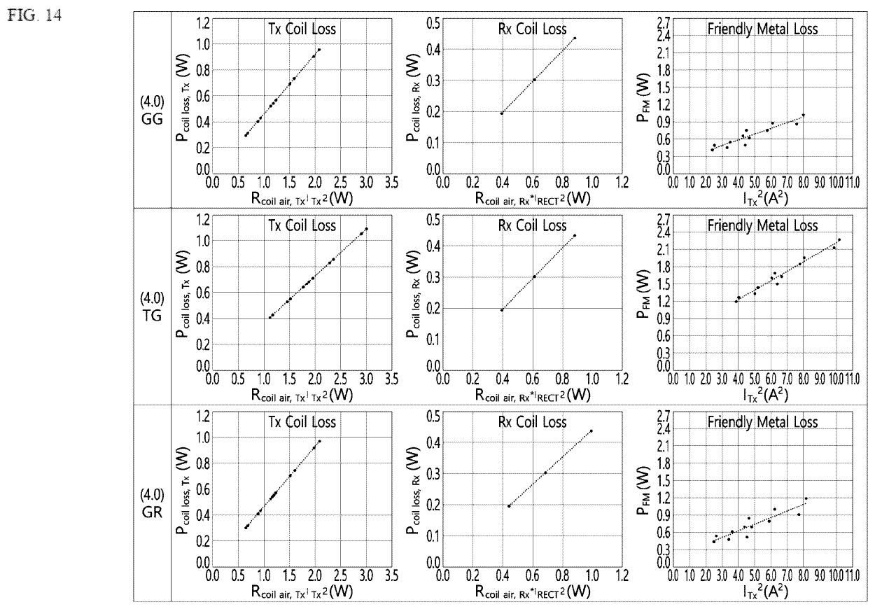

As shown in FIG. 14, the improved MPLA method according to one embodiment of the invention derives linear models for P_{FM} after adjusting d_{z1} of the reference transmitter to 4.0 mm under GG, TG, and GR conditions for the general transmitter with d_{z1} of 4.0 mm. The MPLA coefficients under each condition are shown in Table 10.

TABLE 10

| | b_{coil} | m_{coil} | α_{FM} | α_{FM, DC} |
|---|---|---|---|---|
| GG | 0.4649 | 0.4939 | 0.0997 | 0.1773 |
| TG | 0.3661 | 0.4939 | 0.1651 | 0.5803 |
| GR | 0.4650 | 0.4385 | 0.1157 | 0.1677 |

Further, the scaling factors after adjusting d_{z1} of the reference transmitter to 4.0 mm are shown in Table 11.

TABLE 11

| g_{coil, Tx} | g_{coil, Rx} | g_{FM} | g_{FM, DC} |
|---|---|---|---|
| 1.000 | 1.000 | 1.6560 | 3.2730 |

According to one embodiment of the invention, the improved MPLA method may estimate P_{FM} after adjusting d_{z1} of the reference transmitter to match d_{z1} of the general transmitter under the TR condition for the general transmitter with d_{z1} of 4.0 mm.

Specifically, when d_{z1} of the reference transmitter is adjusted to match d_{z1} of the general transmitter (i.e., 4.0 mm), the estimated value of P_{coil loss,Tx} is calculated as

$${\hat{P}}_{coil loss , Tx} = {b}_{coil}^{TR} {R}_{coil air , Tx} {I}_{Tx}^{2} \approx {g}_{coil , Tx} {b}_{coil}^{TG} {R}_{coil air , Tx} {I}_{Tx}^{2} = {b}_{coil}^{TG} {R}_{coil air , Tx} {I}_{Tx}^{2} = 0.3661 {R}_{coil air , Tx} {I}_{Tx}^{2} ,$$

and the estimated value of P_{coil loss,Rx} is calculated as

$${\hat{P}}_{coil loss , Rx} = {m}_{coil}^{TR} {R}_{coil air , Rx} {I}_{RECT}^{2} \approx {g}_{coil , Rx} {m}_{coil}^{GR} {R}_{coil air , Rx} {I}_{RECT}^{2} = {m}_{coil}^{GR} {R}_{coil air , Rx} {I}_{RECT}^{2} = 0.4385 {R}_{coil air , Rx} {I}_{RECT}^{2} .$$

The estimated value of P_{FM} is calculated as

$${\hat{P}}_{FM} = {α}_{FM}^{TR} {I}_{Tx}^{2} + {α}_{FM , DC}^{TR} \approx {g}_{FM} {α}_{FM}^{GR} {I}_{Tx}^{2} + {g}_{FM , DC} {α}_{FM , DC}^{GR} = 1.656 \times 0.1157 {I}_{Tx}^{2} + 3.273 \times 0.1677 = 0.1916 {I}_{Tx}^{2} + 0.5489 .$$

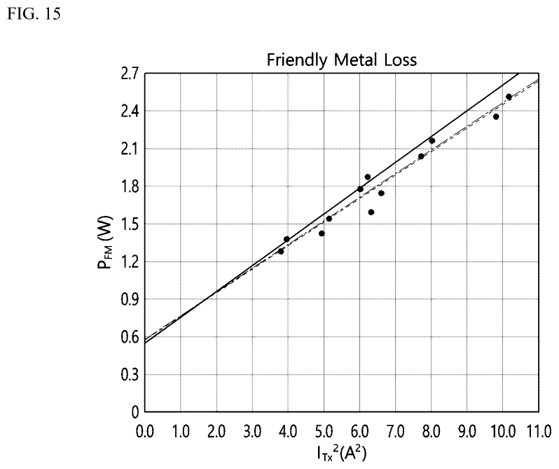

FIG. 15 shows a linear model for P_{FM} derived by the improved MPLA method under the TR condition for the general transmitter with d_{z1} of 4.0 mm. The model shown with a dash-dotted line in FIG. 15 is a model derived by the improved MPLA method, and the estimated value of P_{FM} is

$${\hat{P}}_{FM} = 0.1916 {I}_{Tx}^{2} + 0.5489 .$$

The model shown with a solid line is a model derived by the conventional MPLA method, and the estimated value of P_{FM} is

$${\hat{P}}_{FM} = 0.2063 {I}_{Tx}^{2} + 0.5486 .$$

The model shown with a dotted line is an ideal model, and the estimated value of P_{FM} is

$${\hat{P}}_{FM} = 0.187 {I}_{Tx}^{2} + 0.5802 .$$

According to one embodiment of the invention, RMSEs of the three models shown in FIG. 15 are shown in Table 12. The unit is mW.

TABLE 12

| | | Model according to | Model according |
|---|---|---|---|
| | Ideal | the conventional | to the improved |
| | model | MPLA method | MPLA method |
| RMSE | 80.9 | 130.4 | 81.4 |

According to one embodiment of the invention, the model according to the improved MPLA method demonstrates RMSE performance advantage of about 37.6% compared to the model according to the conventional MPLA method.

According to one embodiment of the invention, two approaches may be considered for implementing the improved MPLA method in the transmitter and receiver under the condition that the receiver cooperates.

First, the first approach will be described.

The general transmitter may store a scaling factor according to d_{z1} of the general transmitter. Specifically, the general transmitter may store (g_{FM,x},g_{FM,DC,x}) corresponding to the scaling factor according to d_{z1} of the general transmitter. Here, the subscript x may refer to d_{z1} of the general transmitter. More specifically, if x is h, it may mean that the general transmitter is for household use and d_{z1} is 1.2 mm, and if x is v, it may mean that the general transmitter is for vehicle use and d_{z1} is 2.0 mm. That is, (g_{FM,h},g_{FM,DC,h}) may be stored in the general transmitter if d_{z1} of the general transmitter is 1.2 mm, and (g_{FM,v},g_{FM,DC,v}) may be stored in the general transmitter if d_{z1} of the general transmitter is 2.0 mm. However, the use of the general transmitter is not limited to household or vehicle use, and d_{z1} of the general transmitter is also not limited to 1.2 mm or 2.0 mm.

The general receiver may store a set of MPLA coefficients. That is, the general receiver may store as many MPLA coefficients as the number of defined d_{z1}. Specifically, the general receiver may store

$$\{ {α}_{FM , x}^{GR} , {α}_{FM , DC , x}^{GR} \} ,$$

which is a set of MPLA coefficients including as many MPLA coefficients as the number of defined d_{z1}, where the subscript x may refer to d_{z1}. For example, if d_{z1} is defined as 1.2 mm and 2.0 mm, the general receiver may store both

$$( {α}_{FM , h}^{GR} , {α}_{FM , DC , h}^{GR} ) ,$$

which is an MPLA coefficient meaning d_{z1} is 1.2 mm, and

$$( {α}_{FM , v}^{GR} , {α}_{FM , DC , v}^{GR} ) ,$$

which is an MPLA coefficient meaning d_{z1} is 2.0 mm. However, the defined d_{z1} is not limited to 1.2 mm or 2.0 mm, and multiple d_{z1} may be defined.

Further, the general transmitter may transmit g_{coil,Rx} to the general receiver using a PLAP packet (in some cases, the PLAP packet transmitted from the receiver to the transmitter may be referred to as a first packet).

Further, the general receiver may transmit g_{coil,Tx} and

$$\{ {α}_{FM , x}^{GR} , {α}_{FM , DC , x}^{GR} \}$$

to the general transmitter using the PLAP packet. Here, by assigning the defined d_{z1} to reserved bits of the PLAP packet, information on d_{z1} corresponding to each MPLA coefficient may be transmitted. Specifically, the PLAP packet may consist of 7 bytes, where a second byte B1 and a third byte B2 may be assigned information corresponding to

$${α}_{FM , x}^{GR} ,$$

a fourth byte B3 and a fifth byte B4 may be assigned information corresponding to

$${α}_{FM , DC , x}^{GR} ,$$

and a sixth byte B5 and a seventh byte B6 may be assigned information corresponding to g_{coil,Tx}. Here, bits b7 to b0 of a first byte B0 of the PLAP packet may be reserved bits that may be assigned information corresponding to conditions of d_{z1} to be applied to

$${α}_{FM , x}^{GR} and {α}_{FM , DC , x}^{GR} .$$

For example, the reserved bits of the PLAP packet may be assigned 0 if d_{z1} is 1.2 mm, and may be assigned 1 if d_{z1} is 2.0 mm. Here, the MPLA coefficient corresponding to 0 in the reserved bits may be

$$( {α}_{FM , h}^{GR} , {α}_{FM , DC , h}^{GR} ) ,$$

and the MPLA coefficient corresponding to 1 in the reserved bits may be

$$( {α}_{FM , v}^{GR} , {α}_{FM , DC , v}^{GR} ) .$$

However, the method of assigning the defined d_{z1} to the reserved bits is not limited to the above example. Additionally, multiple d_{z1} may be defined and assigned to the reserved bits of the PLAP packet.

Further, the general transmitter may estimate P_{FM} using the MPLA coefficient corresponding to d_{z1} of the general transmitter. Specifically, the general transmitter may select the MPLA coefficient corresponding to d_{z1} of the general transmitter among the set of MPLA coefficients

$$\{ {α}_{FM , x}^{GR} , {α}_{FM , DC , x}^{GR} \}$$

with reference to the reserved bits of the PLAP packet received from the general receiver, and may estimate P_{FM} using the stored scaling factor. A relationship equation for estimating P_{FM} of the general transmitter is

$${\hat{P}}_{FM} = {g}_{FM , x} {α}_{FM , x} {I}_{Tx}^{2} + {g}_{FM , DC , x} {α}_{FM , DC , x} ,$$

where the subscript x may refer to d_{z1}. For example, if d_{z1} of the general transmitter is 1.2 mm, the general transmitter may select

$$( {α}_{FM , h}^{GR} , {α}_{FM , DC , h}^{GR} ) ,$$

which is the MPLA coefficient corresponding to the value 0 in the reserved bits of the PLAP packet, and may estimate P_{FM} through

$${\hat{P}}_{FM} = {g}_{FM , h} {α}_{FM , h} {I}_{Tx}^{2} + {g}_{FM , DC , h} {α}_{FM , DC , h} .$$

On the other hand, if d_{z1} of the general transmitter is 2.0 mm, the general transmitter may select

$$( {α}_{FM , v}^{GR} , {α}_{FM , DC , v}^{GR} )$$

corresponding to the value 1 in the reserved bits of the PLAP packet, and may estimate P_{FM} through

$${\hat{P}}_{FM} = {g}_{FM , v} {α}_{FM , v} {I}_{Tx}^{2} + {g}_{FM , DC , v} {α}_{FM , DC , v} .$$

Meanwhile, the general transmitter may estimate P_{coil loss,Tx} in addition to P_{FM}, and the general receiver may estimate P_{coil loss,Rx}.

Next, the second approach will be described.

The general transmitter may store a scaling factor according to d_{z1} of the general transmitter. Specifically, the general transmitter may store (g_{FM,x},g_{FM,DC,x}) corresponding to the scaling factor according to d_{z1} of the general transmitter. Here, the subscript x may refer to d_{z1} of the general transmitter. More specifically, if x is h, it may mean that the general transmitter is for household use and d_{z1} is 1.2 mm, and if x is v, it may mean that the general transmitter is for vehicle use and d_{z1} is 2.0 mm. That is, (g_{FM,h},g_{FM,DC,h}) may be stored in the general transmitter if d_{z1} of the general transmitter is 1.2 mm, and (g_{FM,v},g_{FM,DC,v}) may be stored in the general transmitter if d_{z1} of the general transmitter is 2.0 mm. However, the use of the general transmitter is not limited to household or vehicle use, and d_{z1} of the general transmitter is also not limited to 1.2 mm or 2.0 mm.

The general receiver may store a set of MPLA coefficients. That is, the general receiver may store as many MPLA coefficients as the number of defined d_{z1}. Specifically, the general receiver may store

$$\{ {α}_{FM , x}^{GR} , {α}_{FM , DC , x}^{GR} \} ,$$

which is a set of MPLA coefficients including as many MPLA coefficients as the number of defined d_{z1}, where the subscript x may refer to d_{z1}. For example, if d_{z1} is defined as 1.2 mm and 2.0 mm, the general receiver may store both

$$( {α}_{FM , h}^{GR} , {α}_{FM , DC , h}^{GR} ) ,$$

which is an MPLA coefficient meaning d_{z1} is 1.2 mm, and

$$( {α}_{FM , v}^{GR} , {α}_{FM , DC , v}^{GR} ) ,$$

which is an MPLA coefficient meaning d_{z1} is 2.0 mm. However, the defined d_{z1} is not limited to 1.2 mm or 2.0 mm, and multiple d_{z1} may be defined.

Further, at the request of the general receiver, the general transmitter may transmit information on d_{z1} of the general transmitter to the general receiver using an XID packet (in some cases, the XID packet transmitted from the receiver to the transmitter may be referred to as a second packet). Specifically, by assigning d_{z1} of the general transmitter to reserved bits of the XID packet, the information on d_{z1} of the general transmitter may be transmitted to the general receiver. More specifically, the XID packet may consist of 9 bytes, where a fifth byte B4 through a seventh byte B6 may be assigned information on a device identifier, and the seventh byte B6 through a ninth byte B8 may be manufacturing reserved bits. Here, a first byte B0 through the fifth byte B4 of the XID packet may be reserved bits that may be assigned information corresponding to conditions of d_{z1} of the general transmitter. For example, if d_{z1} of the general transmitter is 1.2 mm, the reserved bits of the XID packet may be assigned 0 and transmitted to the general receiver. On the other hand, if d_{z1} of the general transmitter is 2.0 mm, the reserved bits of the XID packet may be assigned 1 and transmitted to the general receiver. However, d_{z1} of the general transmitter is not limited to 1.2 mm or 2.0 mm. Additionally, the method of assigning the information corresponding to d_{z1} of the general transmitter to the XID packet is not limited to the above example.

Further, the general transmitter may transmit g_{coil,Rx} to the general receiver using the PLAP packet.

Further, the general receiver may transmit g_{coil,Tx} and

$$( {α}_{FM , x}^{GR} , {α}_{FM , DC , x}^{GR} ) ,$$

which is an MPLA coefficient corresponding to d_{z1} of the general transmitter, to the general transmitter using the PLAP packet. Specifically, the general receiver may identify d_{z1} of the general transmitter with reference to the reserved bits of the XID packet, and may select and transmit

$$( {α}_{FM , x}^{GR} , {α}_{FM , DC , x}^{GR} ) ,$$

which is the MPLA coefficient corresponding to d_{z1} of the general transmitter, to the general transmitter. More specifically, the PLAP packet may consist of 7 bytes, where a second byte B1 and a third byte B2 may be assigned information corresponding to

$${α}_{FM , x}^{GR} ,$$

a fourth byte B3 and a fifth byte B4 may be assigned information corresponding to

$${α}_{FM , DC , x}^{GR} ,$$

and a sixth byte B5 and a seventh byte B6 may be assigned information corresponding to g_{coil,Tx}. Here, bits b7 to b0 of a first byte B0 of the PLAP packet may be reserved bits. For example, If the value of the reserved bits of the XID packet received from the general transmitter is 0, the general receiver may identify d_{z1} of the general transmitter as 1.2 mm, and may select

$$( {α}_{FM , h}^{GR} , {α}_{FM , DC , h}^{GR} )$$

among

$$\{ {α}_{FM , x}^{GR} , {α}_{FM , DC , x}^{GR} \}$$

and transmit it to the general transmitter. On the other hand, if the value of the reserved bits of the XID packet is 1, the general receiver may identify d_{z1} of the general transmitter as 2.0 mm, and may select

$$( {α}_{FM , v}^{GR} , {α}_{FM , DC , v}^{GR} )$$

among

$$\{ {α}_{FM , x}^{GR} , {α}_{FM , DC , x}^{GR} \}$$

and transmit it to the general transmitter.

Further, the general transmitter may estimate P_{FM} using the MPLA coefficient received from the general receiver. A relationship equation for estimating P_{FM} of the general transmitter is

$${\hat{P}}_{FM} = {g}_{FM , x} {α}_{FM , x} {I}_{Tx}^{2} + {g}_{FM , DC , x} {α}_{FM , DC , x} .$$

For example, if d_{z1} of the general transmitter is 1.2 mm, the general transmitter may receive

$$( {α}_{FM , h}^{GR} , {α}_{FM , DC , h}^{GR} )$$

from the general receiver, and may estimate P_{FM} through

$${\hat{P}}_{FM} = {g}_{FM , h} {α}_{FM , h} {I}_{Tx}^{2} + {g}_{FM , DC , h} {α}_{FM , DC , h} .$$

On the other hand, if d_{z1} of the general transmitter is 2.0 mm, the general transmitter may receive

$$( {α}_{FM , v}^{GR} , {α}_{FM , DC , v}^{GR} )$$

from the general receiver, and may estimate P_{FM} through

$${\hat{P}}_{FM} = {g}_{FM , v} {α}_{FM , v} {I}_{Tx}^{2} + {g}_{FM , DC , v} {α}_{FM , DC , v} .$$

Meanwhile, the general transmitter may estimate P_{coil loss,Tx} in addition to P_{FM}, and the general receiver may estimate P_{coil loss,Rx}.

### Second Embodiment: Improved MPLA Method Under the Condition that the General Receiver does not Cooperate

According to one embodiment of the invention, two approaches may be considered for implementing the improved MPLA method in the transmitter and receiver when the general receiver does not cooperate under the condition that d_{z1} of the general transmitter is not 1.2 mm.

First, the first approach will be described.

The general receiver may store an MPLA coefficient according to d_{z1} of the reference transmitter. Specifically,

$$( {α}_{FM}^{GR} , {α}_{FM , DC}^{GR} )$$

may be calculated and stored in the general receiver.

A scaling factor according to d_{z1} of the general transmitter may be calculated and stored in the general transmitter. Specifically, the general transmitter may calculate a scaling factor (g_{FM},g_{FM,DC}) on the basis of d_{z1} of the general transmitter. More specifically, the scaling factor may be calculated by placing a gap equal to the difference between d_{z1} of the general transmitter and d_{z1} of the reference transmitter on an interface of the reference transmitter. For example, if d_{z1} of the reference transmitter is 1.2 mm and d_{z1} of the general transmitter is 2.0 mm, the scaling factor may be calculated after placing air, an acrylic plate, or the like with thickness of 0.8 mm on the interface of the reference transmitter.

Further, the general receiver may transmit the MPLA coefficient

$$( {α}_{FM}^{GR} , {α}_{FM , DC}^{GR} )$$

to the general transmitter using the PLAP packet. Specifically, the PLAP packet may consist of 7 bytes, where a second byte B1 and a third byte B2 may be assigned information corresponding to

$${α}_{FM}^{GR} ,$$

a fourth byte B3 and a fifth byte B4 may be assigned information corresponding to

$${α}_{FM , DC}^{GR} ,$$

and a sixth byte B5 and a seventh byte B6 may be assigned information corresponding to g_{coil,Tx}. Here, bits b7 to b0 of a first byte B0 of the PLAP packet may be reserved bits.

Further, the general transmitter may estimate P_{FM} using the MPLA coefficient received from the general receiver and the scaling factor according to d_{z1} of the general transmitter. Specifically, the general transmitter may estimate P_{FM} using

$$( {α}_{FM}^{GR} , {α}_{FM , DC}^{GR} )$$

received from the general receiver and (g_{FM},g_{FM,DC}) calculated by the general transmitter. A relationship equation for estimating P_{FM} of the general transmitter is

$${\hat{P}}_{FM} = {g}_{FM} {α}_{FM} {I}_{Tx}^{2} + {g}_{FM , DC} {α}_{FM , DC} \approx {g}_{FM} {α}_{FM}^{GR} {I}_{Tx}^{2} + {g}_{FM , DC} {α}_{FM , DC}^{GR} .$$

Next, the second approach will be described.

The general receiver may store a scaling factor according to d_{z1} of the reference transmitter. Specifically, (g_{FM},g_{FM,DC}) may be calculated and stored in the general receiver. Here, the scaling factor may be calculated as

$${g}_{FM} = {α}_{FM}^{GR} / {α}_{FM}^{GG} \approx {α}_{FM}^{TR} / {α}_{FM}^{TG} and$$

$${g}_{FM , DC} = {α}_{FM , DC}^{GR} / {α}_{FM , DC}^{GG} \approx {α}_{FM , DC}^{TR} / {α}_{FM , DC}^{TG} .$$

An MPLA coefficient according to d_{z1} of the general transmitter may be calculated and stored in the general transmitter. Specifically, an MPLA coefficient

$$( {α}_{FM}^{TG} , {α}_{FM , DC}^{TG} )$$

according to d_{z1} of the general transmitter may be calculated and stored in the general transmitter.

Further, the general receiver may transmit the scaling factor (g_{FM},g_{FM,DC}) to the general transmitter using the PLAP packet. Specifically, the PLAP packet may consist of 7 bytes, where a second byte B1 and a third byte B2 may be assigned information corresponding to g_{FM}, a fourth byte B3 and a fifth byte B4 may be assigned information corresponding to g_{FM,DC}, and a sixth byte B5 and a seventh byte B6 may be assigned information corresponding to g_{coil,Tx}. Here, bits b7 to b0 of a first byte B0 of the PLAP packet may be reserved bits.

Further, the general transmitter may estimate P_{FM} using the scaling factor received from the general receiver and the MPLA coefficient according to d_{z1} of the general transmitter. Specifically, the general transmitter may estimate P_{FM} using (g_{FM},g_{FM,DC}) received from the general receiver and the MPLA coefficient

$$( {α}_{FM}^{TG} , {α}_{FM , DC}^{TG} )$$

according to d_{z1} of the general transmitter. A relationship equation for estimating P_{FM} of the general transmitter is

$${\hat{P}}_{FM} = {g}_{FM} {α}_{FM} {I}_{Tx}^{2} + {g}_{FM , DC} {α}_{FM , DC} \approx {g}_{FM} {α}_{FM}^{TG} {I}_{Tx}^{2} + {g}_{FM , DC} {α}_{FM , DC}^{TG} .$$

Although the present invention has been described above in terms of specific items such as detailed elements as well as the limited embodiments and the drawings, they are only provided to help more general understanding of the invention, and the present invention is not limited to the above embodiments. It will be appreciated by those skilled in the art to which the present invention pertains that various modifications and changes may be made from the above description.

Therefore, the spirit of the present invention shall not be limited to the above-described embodiments, and the entire scope of the appended claims and their equivalents will fall within the scope and spirit of the invention.

1. A method for accounting for power loss,
wherein the method is implemented in a wireless power transmitter and comprises the steps of:
by the wireless power transmitter, acquiring information on a first distance between an upper surface of a coil of the wireless power transmitter and an upper surface of an interface of the wireless power transmitter, and a second distance between an upper surface of a coil of a reference transmitter and an upper surface of an interface of the reference transmitter; and
by the wireless power transmitter, estimating power loss due to friendly metal with reference to the acquired information,
wherein the wireless power transmitter is configured to estimate the power loss after adjusting the second distance to match the first distance,
wherein the friendly metal is a metal included in at least one of the wireless power transmitter and a wireless power receiver, and causes the power loss by absorbing a part of power transmitted during wireless power transmission and reception, and
wherein the reference transmitter is a transmitter with standardized specifications.

2. The method of claim 1, wherein the first distance is capable of varying depending on use of the wireless power transmitter.

3. The method of claim 1, wherein a first packet transmitted from the wireless power receiver includes information on a coefficient used to estimate the power loss, and
wherein in the estimating step, the power loss of the wireless power transmitter is estimated with reference to the coefficient corresponding to the first distance and a factor corresponding to the first distance used to estimate the power loss.

4. The method of claim 1, wherein a second packet transmitted to the wireless power receiver includes information the first distance,
wherein a first packet transmitted from the wireless power receiver includes information on a coefficient corresponding to the first distance used to estimate the power loss, and
wherein in the estimating step, the power loss of the wireless power transmitter is estimated with reference to the coefficient and a factor corresponding to the first distance used to estimate the power loss.

5. The method of claim 1, wherein a first packet transmitted from the wireless power receiver includes information on a coefficient corresponding to the second distance used to estimate the power loss, and
wherein in the estimating step, the power loss of the wireless power transmitter is estimated with reference to the coefficient and a factor corresponding to the first distance used to estimate the power loss.

6. The method of claim 1, wherein a first packet transmitted from the wireless power receiver includes information on a factor corresponding to the second distance used to estimate the power loss, and
wherein in the estimating step, the power loss of the wireless power transmitter is estimated with reference to the factor and a coefficient corresponding to the first distance used to estimate the power loss.

7. A wireless power transmitter,
wherein the wireless power transmitter is configured to:
acquire information on a first distance between an upper surface of a coil of the wireless power transmitter and an upper surface of an interface of the wireless power transmitter, and a second distance between an upper surface of a coil of a reference transmitter and an upper surface of an interface of the reference transmitter; and
estimate power loss due to friendly metal with reference to the acquired information,
wherein the wireless power transmitter is configured to estimate the power loss after adjusting the second distance to match the first distance,
wherein the friendly metal is a metal included in at least one of the wireless power transmitter and a wireless power receiver, and causes the power loss by absorbing a part of power transmitted during wireless power transmission and reception, and
wherein the reference transmitter is a transmitter with standardized specifications.

8. The wireless power transmitter of claim 7, wherein the first distance is capable of varying depending on use of the wireless power transmitter.

9. The wireless power transmitter of claim 7, wherein a first packet transmitted from the wireless power receiver includes information on a coefficient used to estimate the power loss, and
wherein the wireless power transmitter is configured to estimate the power loss of the wireless power transmitter with reference to the coefficient corresponding to the first distance and a factor corresponding to the first distance used to estimate the power loss.

10. The wireless power transmitter of claim 7, wherein a second packet transmitted to the wireless power receiver includes information the first distance,
wherein a first packet transmitted from the wireless power receiver includes information on a coefficient corresponding to the first distance used to estimate the power loss, and
wherein the wireless power transmitter is configured to estimate the power loss of the wireless power transmitter with reference to the coefficient and a factor corresponding to the first distance used to estimate the power loss.

11. The wireless power transmitter of claim 7, wherein a first packet transmitted from the wireless power receiver includes information on a coefficient corresponding to the second distance used to estimate the power loss, and
wherein the wireless power transmitter is configured to estimate the power loss of the wireless power transmitter with reference to the coefficient and a factor corresponding to the first distance used to estimate the power loss.

12. The wireless power transmitter of claim 7, wherein a first packet transmitted from the wireless power receiver includes information on a factor corresponding to the second distance used to estimate the power loss, and
wherein the wireless power transmitter is configured to estimate the power loss of the wireless power transmitter with reference to the factor and a coefficient corresponding to the first distance used to estimate the power loss.

13. A method for accounting for power loss,
wherein the method is implemented in a wireless power receiver and comprises the steps of:
by the wireless power receiver, acquiring information required for a wireless power transmitter to estimate power loss due to friendly metal; and
by the wireless power receiver, transmitting the acquired information to the wireless power transmitter,
wherein the wireless power transmitter is configured to estimate the power loss due to friendly metal with reference to the acquired information,
wherein the wireless power transmitter is configured to estimate the power loss after adjusting a second distance between an upper surface of a coil of a reference transmitter and an upper surface of an interface of the reference transmitter to match a first distance between an upper surface of a coil of the wireless power transmitter and an upper surface of an interface of the wireless power transmitter,
wherein the friendly metal is a metal included in at least one of the wireless power transmitter and the wireless power receiver, and causes the power loss by absorbing a part of power transmitted during wireless power transmission and reception, and
wherein the reference transmitter is a transmitter with standardized specifications.

14. The method of claim 13, wherein the first distance is capable of varying depending on use of the wireless power transmitter.

15. The method of claim 13, wherein a first packet transmitted to the wireless power transmitter includes information on a coefficient used to estimate the power loss, and
wherein the wireless power transmitter is configured to estimate the power loss of the wireless power transmitter with reference to the coefficient corresponding to the first distance and a factor corresponding to the first distance used to estimate the power loss.

16. The method of claim 13, wherein a second packet transmitted from the wireless power transmitter includes information the first distance,
wherein a first packet transmitted to the wireless power transmitter includes information on a coefficient corresponding to the first distance used to estimate the power loss, and
wherein the wireless power transmitter is configured to estimate the power loss of the wireless power transmitter with reference to the coefficient and a factor corresponding to the first distance used to estimate the power loss.

17. The method of claim 13, wherein a first packet transmitted to the wireless power transmitter includes information on a coefficient corresponding to the second distance used to estimate the power loss, and
wherein the wireless power transmitter is configured to estimate the power loss of the wireless power transmitter with reference to the coefficient and a factor corresponding to the first distance used to estimate the power loss.

18. The method of claim 13, wherein a first packet transmitted to the wireless power transmitter includes information on a factor corresponding to the second distance used to estimate the power loss, and
wherein the wireless power transmitter is configured to estimate the power loss of the wireless power transmitter with reference to the factor and a coefficient corresponding to the first distance used to estimate the power loss.

19. A wireless power receiver,
wherein the wireless power receiver is configured to:
acquire information required for a wireless power transmitter to estimate power loss due to friendly metal; and
transmit the acquired information to the wireless power transmitter,
wherein the wireless power transmitter is configured to estimate the power loss due to friendly metal with reference to the acquired information,
wherein the wireless power transmitter is configured to estimate the power loss after adjusting a second distance between an upper surface of a coil of a reference transmitter and an upper surface of an interface of the reference transmitter to match a first distance between an upper surface of a coil of the wireless power transmitter and an upper surface of an interface of the wireless power transmitter,
wherein the friendly metal is a metal included in at least one of the wireless power transmitter and the wireless power receiver, and causes the power loss by absorbing a part of power transmitted during wireless power transmission and reception, and
wherein the reference transmitter is a transmitter with standardized specifications.

20. The wireless power receiver of claim 19, wherein the first distance is capable of varying depending on use of the wireless power transmitter.

21. The wireless power receiver of claim 19, wherein a first packet transmitted to the wireless power transmitter includes information on a coefficient used to estimate the power loss, and
wherein the wireless power transmitter is configured to estimate the power loss of the wireless power transmitter with reference to the coefficient corresponding to the first distance and a factor corresponding to the first distance used to estimate the power loss.

22. The wireless power receiver of claim 19, wherein a second packet transmitted from the wireless power transmitter includes information the first distance,
wherein a first packet transmitted to the wireless power transmitter includes information on a coefficient corresponding to the first distance used to estimate the power loss, and
wherein the wireless power transmitter is configured to estimate the power loss of the wireless power transmitter with reference to the coefficient and a factor corresponding to the first distance used to estimate the power loss.

23. The wireless power receiver of claim 19, wherein a first packet transmitted to the wireless power transmitter includes information on a coefficient corresponding to the second distance used to estimate the power loss, and
wherein the wireless power transmitter is configured to estimate the power loss of the wireless power transmitter with reference to the coefficient and a factor corresponding to the first distance used to estimate the power loss.

24. The wireless power receiver of claim 19, wherein a first packet transmitted to the wireless power transmitter includes information on a factor corresponding to the second distance used to estimate the power loss, and
wherein the wireless power transmitter is configured to estimate the power loss of the wireless power transmitter with reference to the factor and a coefficient corresponding to the first distance used to estimate the power loss.
